(19) United States
(12) Patent Application Publication
(10) Pub. No.: US 2009/0066396 A1
(43) Pub. Date: Mar. 12, 2009

(54) LEVEL SHIFTING CIRCUIT

(75) Inventors: Yu-Hsin Lin, Taipei City (TW); Hsueh-Kun Liao, Hsin-Chu Hsien (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/853,053

(22) Filed: Sep. 11, 2007

(51) Int. Cl. H03K 3/012

(52) U.S. Cl. 327/333

(57) ABSTRACT

A level shifting circuit is provided. Thin oxide devices are utilized to reduce the threshold, and thick oxide devices are utilized to protect the thin oxides from breakdown. An input voltage input voltage swings between a low supply voltage and ground. An output voltage swings between a high supply voltage and the ground. An inverter with input connected to the input voltage, outputs an inverted input voltage. The input voltage is subsequently between 0.5V to 2.5V, and the output voltage is subsequently between 3V to 10V.

### BACKGROUND

The invention relates to level shifting, and in particular, to a level shifting circuit that avoids transistor breakdown.

Ultra deep submicron CMOS technologies are used to create digital integrated circuits with very high transistor densities and very high switching speeds. These submicron CMOS transistors have specifically designed thin gate oxide and low threshold voltages. To facilitate use of ultra deep submicron CMOS processes, the supply voltage for the high density logic core must be lowered to improve device reliability. Supply voltages of between about 2.5V and 3.3V are typical for conventional CMOS logic devices; have to be reduced to a low voltage regime of, for example, between about 0.9V and 2.5V.

As the supply voltage of the core logic section is reduced, the supply voltage for the input/output section of the integrated circuit must be kept higher to assure adequate signal-to-noise ratio and compatibility with other devices. When digital signals in the low voltage core must be transmitted off the integrated circuit, signal level shifting is therefore desirable. A level shifting circuit is used to increase the upper voltage swing of the low voltage signal, from a low voltage to a high voltage.

FIG. 1 shows a conventional level shifting circuit. Four transistors and one converter are utilized in the circuit. The first thick oxide NMOS transistor NG1 and second thick oxide NMOS transistor NG2 are thick oxide NMOS transistors, having a threshold voltage of between 0.4V and 0.7V. The first thick oxide PMOS transistor PG1 and second thick oxide PMOS transistor PG2 are thick oxide PMOS transistors, having a threshold voltage of between −0.4V and −0.7V. Generally, the low supply voltage VCCL is biased at between about 0.9V and 2.5V. The high supply voltage VCCH is biased at between about 3V and 5V. The level shifting circuit converts an input voltage Vᵢₙ between 0 Volts to low supply voltage VCCL Volts, to an output voltage Vout between 0 Volts and high supply voltage VCCH Volts. Since the high supply voltage VCCH is applied to the first thick oxide PMOS transistor PG1, second thick oxide PMOS transistor PG2, first thick oxide NMOS transistor NG1 and second thick oxide NMOS transistor NG2, reliability concerns for the thin oxide devices are negligible. The threshold voltages of the thick oxide devices, however, are relatively high in comparison to low core voltages. The first thick oxide NMOS transistor NG1 and second thick oxide NMOS transistor NG2 may not be fully turned on for low core voltage devices, thus level shifting performance is affected.

### SUMMARY

An exemplary level shifting circuit is provided, comprising an input voltage swinging between a low supply voltage and ground, an output voltage swinging between a high supply voltage and the ground, an inverter with input connected to the input voltage, outputting an inverted input voltage, a first NMOS transistor with gate connected to the input voltage and source connected to the ground, a first thick oxide NMOS transistor with gate connected to a first reference voltage and source coupled to the first NMOS transistor drain, a second NMOS transistor with gate connected to the inverted input voltage and source connected to the ground, a second thick oxide NMOS transistor with gate connected to the first reference voltage and source coupled to the second NMOS transistor drain, wherein the second thick oxide NMOS transistor drain is the output voltage, a first thick oxide PMOS transistor with gate connected to the second thick oxide NMOS transistor drain and source connected to the first thick oxide NMOS transistor drain, a second thick oxide PMOS transistor with gate connected to the first thick oxide NMOS transistor drain and source connected to the second thick oxide NMOS transistor drain, a third thick oxide PMOS transistor with gate connected to the input voltage, source connected to the first thick oxide PMOS transistor drain, and drain connected to the high supply voltage, and a fourth thick oxide PMOS transistor with gate connected to the inverted input voltage, source connected to the second thick oxide PMOS transistor drain, and drain connected to the high supply voltage.

### BRIEF DESCRIPTION OF THE DRAWINGS

The following detailed description, given byway of example and not intended to limit the invention solely to the embodiments described herein, will best be understood in conjunction with the accompanying drawings, in which:

FIG. 1 shows a conventional level shifting circuit;

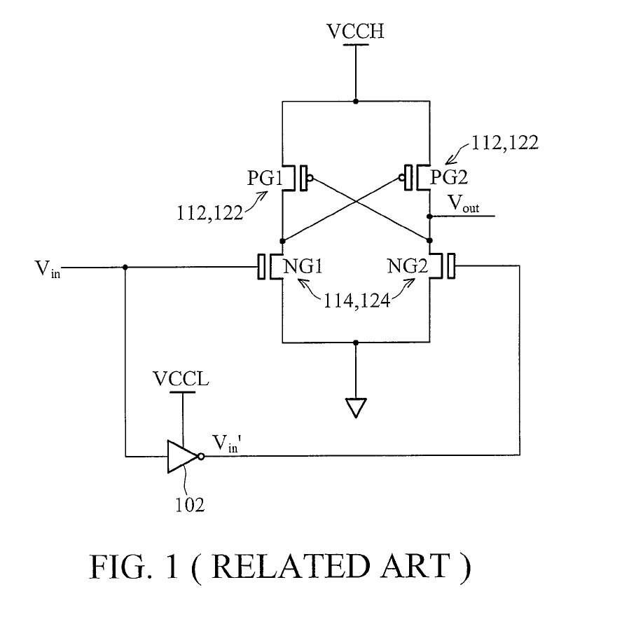

FIG. 2 shows an embodiment of the level shifting circuit;

FIG. 3 shows an embodiment of the level shifting circuit;

FIG. 4 shows an embodiment of the level shifting circuit; and

FIG. 5 shows an embodiment of the level shifting circuit.

### DETAILED DESCRIPTION

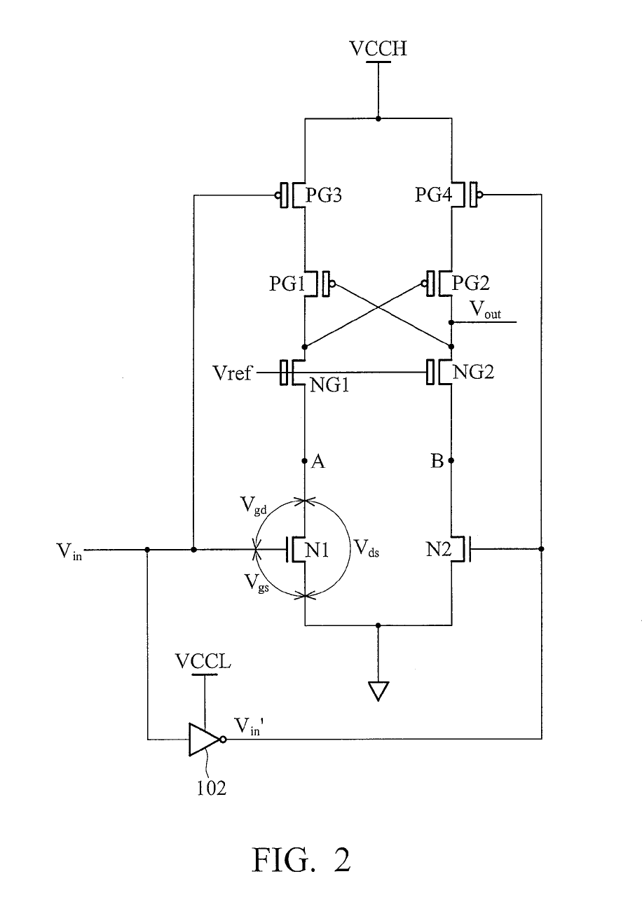

FIG. 2 shows an embodiment of a level shifting circuit. A pair of thin oxide devices, first NMOS transistor N1 and second NMOS transistor N2 are utilized, with gates coupled to the input voltage Vᵢₙ and the inverted input voltage Vᵢₙ′. Since the thin oxide devices have lower threshold voltage of between 0.2V and 0.35V, the level shifting circuit may be fully turned on for low core voltage applications. The gates of first thick oxide NMOS transistor NG1 and second thick oxide NMOS transistor NG2 are coupled to a first reference voltage V_{ref}, such that the voltages on node A and B can be kept under a predetermined value, keeping cross voltages V_{gd}/V_{ds}/V_{gs} of the first NMOS transistor N1 and second NMOS transistor N2 from exceeding a breakdown threshold. In this way, the level shifting circuit operates normally with very low core voltage while the thin oxide devices are protected from breakdown by a first reference voltage V_{ref}. The first NMOS transistor N1 and second NMOS transistor N2 may be specifically designed low threshold voltage devices. The first thick oxide NMOS transistor NG1 and second thick oxide NMOS transistor NG2 may be depletion components such as zero threshold voltage devices or negative threshold voltage devices. The first thick oxide NMOS transistor NG1 and second thick oxide NMOS transistor NG2 are thick oxide NMOS transistors, and the first thick oxide PMOS transistor PG1, second thick oxide PMOS transistor PG2, third thick oxide PMOS transistor PG3 and fourth thick oxide PMOS transistor PG4 are thick oxide PMOS transistors.

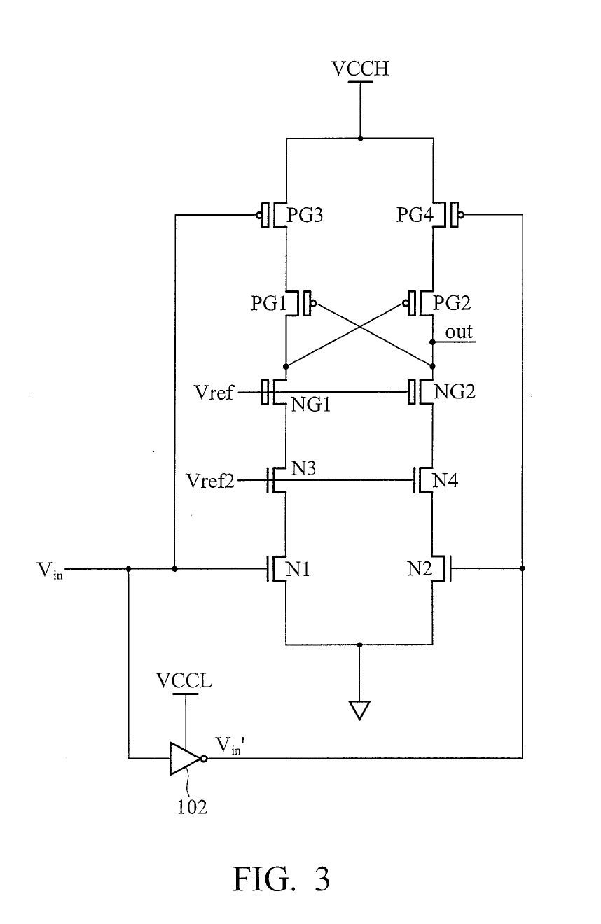

FIG. 3 shows an embodiment of the level shifting circuit. The circuit in FIG. 2 can be further modified. A pair of third NMOS transistor N3 and fourth NMOS transistor N4 is provided, with gates coupled to a second reference voltage V_{ref2}.

The third NMOS transistor N3 source is connected to first NMOS transistor N1 drain, and third NMOS transistor N3 drain connected to the first thick oxide NMOS transistor NG1 source. The fourth NMOS transistor N4 source is connected to second NMOS transistor N2 drain, and fourth NMOS transistor N4 drain connected to the second thick oxide NMOS transistor NG2 source.

The second reference voltage V_{ref2} is typically set to low supply voltage VCCL, thus the third NMOS transistor N3 and fourth NMOS transistor N4 are always on. Since the first NMOS transistor N1, second NMOS transistor N2, third NMOS transistor N3 and fourth NMOS transistor N4 are thin oxide devices in this embodiment, reliability concerns exist. The first reference voltage V_{ref} sent to the gates of first thick oxide NMOS transistor NG1 and second thick oxide NMOS transistor NG2, is carefully chosen to protect the first NMOS transistor N1, second NMOS transistor N2, third NMOS transistor N3 and fourth NMOS transistor N4 from breakdown. The cross voltages V_{gd}/V_{ds}/V_{gs} of the first NMOS transistor N1, second NMOS transistor N2, third NMOS transistor N3 and fourth NMOS transistor N4 are kept lower than the breakdown voltage by the first reference voltage V_{ref} and second reference voltage V_{ref2}. The third NMOS transistor N3 and fourth NMOS transistor N4 are thin oxide NMOS transistors. The breakdown voltage is typically the same the low supply voltage VCCL.

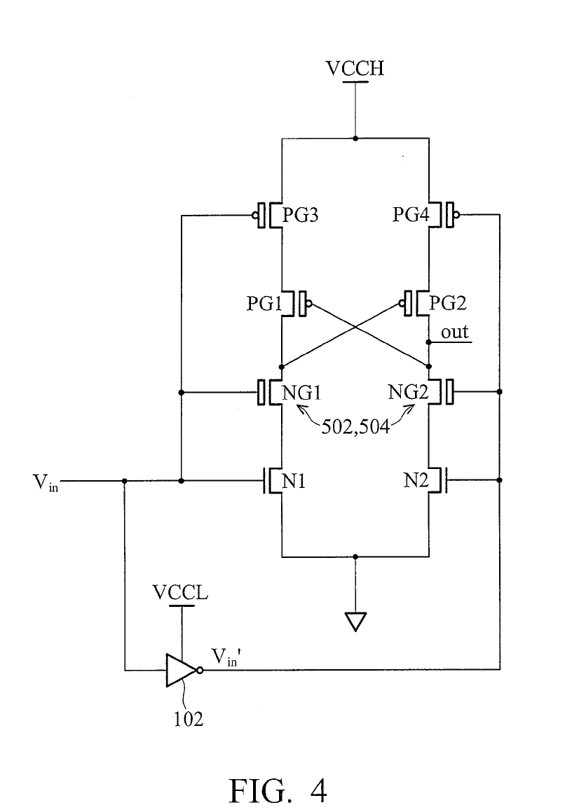

FIG. 4 shows an embodiment of the level shifting circuit. The first thick oxide NMOS transistor NG1 and second thick oxide NMOS transistor NG2 are modified to depletion components, such as zero threshold voltage devices or negative threshold voltage devices. The gates of the first thick oxide NMOS transistor NG1 and second thick oxide NMOS transistor NG2 are respectively connected to the input voltage Vᵢₙ and the inverted input voltage Vᵢₙ′. When input voltage Vᵢₙ is high, the gates of first thick oxide NMOS transistor NG1 and first NMOS transistor N1 are low supply voltage VCCL, thus the first thick oxide NMOS transistor NG1 and first NMOS transistor N1 are turned on, and the first thick oxide NMOS transistor NG1 source/drain are low. Since the source/drain of the first NMOS transistor N1 are both low, the first NMOS transistor N1 avoids breakdown. Simultaneously, the second NMOS transistor N2 and second thick oxide NMOS transistor NG2 are turned off since the inverted input voltage Vᵢₙ′ is ground, thus the second NMOS transistor N2 is also safe from breakdown. Conversely, when the input voltage Vᵢₙ is low, a similar condition applies to the transistors thereof, thus reliability concerns are addressed. The first NMOS transistor N1 and second NMOS transistor N2 are thin oxide NMOS transistors, and the first thick oxide NMOS transistor NG1 and second thick oxide NMOS transistor NG2 are depletion NMOS transistors with threshold voltages no more than zero, while the first thick oxide PMOS transistor PG1, second thick oxide PMOS transistor PG2, third thick oxide PMOS transistor PG3 and fourth thick oxide PMOS transistor PG4 are thick oxide PMOS transistors.

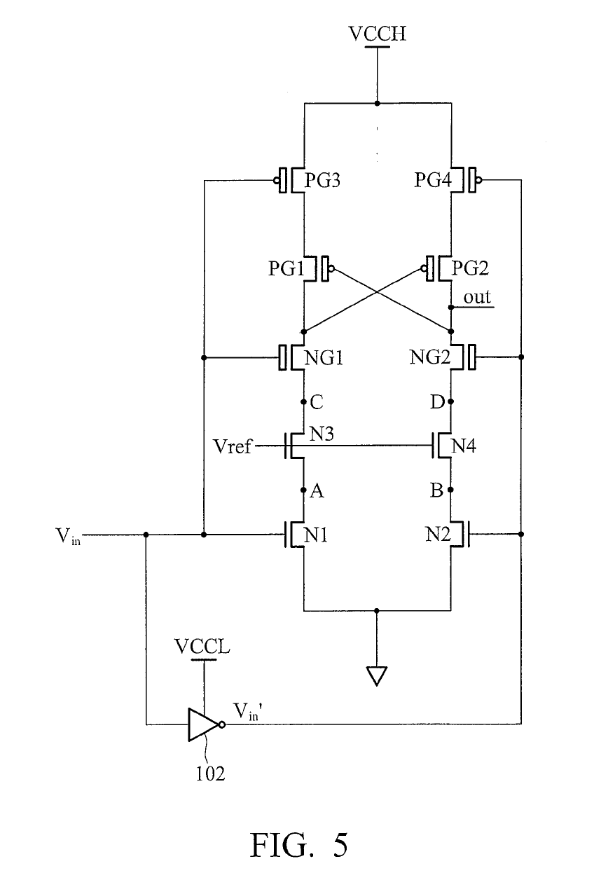

FIG. 5 shows an embodiment of a level shifting circuit. A modification is provided to the embodiment in FIG. 4. A pair of third NMOS transistor N3 and fourth NMOS transistor N4 is provided, with gates coupled to a first reference voltage V_{ref}. The third NMOS transistor N3 source is connected to first NMOS transistor N1 drain, and third NMOS transistor N3 drain connected to the first thick oxide NMOS transistor NG1 source. The fourth NMOS transistor N4 source is connected to second NMOS transistor N2 drain, and fourth NMOS transistor N4 drain connected to the second thick oxide NMOS transistor NG2 source. The first reference voltage V_{ref} is set to low supply voltage VCCL, thus the third NMOS transistor N3 and fourth NMOS transistor N4 are always on. When the input voltage Vᵢₙ is high, the first thick oxide NMOS transistor NG1 and first NMOS transistor N1 are turned on, and voltages on nodes A and C are ground, thus the V_{gd}/V_{ds}/V_{gs} of the first NMOS transistor N1 and third NMOS transistor N3 are kept lower than the breakdown voltage. Simultaneously, the second thick oxide NMOS transistor NG2 and second NMOS transistor N2 are turned off, and the cross voltages therebetween are under the breakdown threshold.

The breakdown voltage may be same with the low supply voltage VCCL. The first NMOS transistor N1, second NMOS transistor N2, third NMOS transistor N3 and fourth NMOS transistor N4 are thin oxide NMOS transistors. In the embodiments, input voltage Vᵢₙ may be subsequently between 0.5V to 2.5V, and output voltage Vout may be subsequently between 3V to 10V.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A level shifting circuit comprising:
an inverter with input connected to an input voltage, outputting an inverted input voltage, wherein the input voltage input voltage swings between a low supply voltage and ground;
a first NMOS transistor with gate connected to the input voltage and source connected to the ground;
a first thick oxide NMOS transistor with gate connected to a first reference voltage and source coupled to the first NMOS transistor drain;
a second NMOS transistor with gate connected to the inverted input voltage and source connected to the ground;
a second thick oxide NMOS transistor with gate connected to the first reference voltage and source coupled to the second NMOS transistor drain, wherein the second thick oxide NMOS transistor drain is an output voltage and the output voltage swings between a high supply voltage and ground;
a first thick oxide PMOS transistor with gate connected to the second thick oxide NMOS transistor drain and source connected to the first thick oxide NMOS transistor drain;
a second thick oxide PMOS transistor with gate connected to the first thick oxide NMOS transistor drain and source connected to the second thick oxide NMOS transistor drain;
a third thick oxide PMOS transistor with gate connected to the input voltage, source connected to the first thick oxide PMOS transistor drain, and drain connected to the high supply voltage; and
a fourth thick oxide PMOS transistor with gate connected to the inverted input voltage, source connected to the second thick oxide PMOS transistor drain, and drain connected to the high supply voltage.

2. The level shifting circuit as claimed in claim 1, wherein:
the first NMOS transistor and second NMOS transistor are thin oxide NMOS transistors.

3. The level shifting circuit as claimed in claim 1, further comprising:
a third NMOS transistor with gate connected to a second reference voltage, source connected to the first NMOS transistor drain, and drain connected to the first thick oxide NMOS transistor source; and
a fourth NMOS transistor with gate connected to the second reference voltage, source connected to the second NMOS transistor drain, and drain connected to the second thick oxide NMOS transistor source.

4. The level shifting circuit as claimed in claim 3, wherein the third NMOS transistor and fourth NMOS transistor are thin oxide NMOS transistors.

5. The level shifting circuit as claimed in claim 1, wherein the input voltage is subsequently between 0.5V to 2.5V.

6. The level shifting circuit as claimed in claim 1, wherein the output voltage is subsequently between 3V to 10V.

7. A level shifting circuit comprising:
an inverter with input connected to an input voltage, outputting an inverted input voltage, wherein the input voltage swings between a low supply voltage and ground;
a first NMOS transistor with gate connected to the input voltage and source connected to the ground;
a first thick oxide NMOS transistor with gate connected to the input voltage and source coupled to the first NMOS transistor drain;
a second NMOS transistor with gate connected to the inverted input voltage and source connected to the ground;
a second thick oxide NMOS transistor with gate connected to the inverted input voltage and source coupled to the second NMOS transistor drain, wherein the second thick oxide NMOS transistor drain is an output voltage, wherein the output voltage Vout swings between a high supply voltage and the ground;
a first thick oxide PMOS transistor with gate connected to the second thick oxide NMOS transistor drain and source connected to the first thick oxide NMOS transistor drain;
a second thick oxide PMOS transistor with gate connected to the first thick oxide NMOS transistor drain and source connected to the second thick oxide NMOS transistor drain;
a third thick oxide PMOS transistor with gate connected to the input voltage, source connected to the first thick oxide PMOS transistor drain, and drain connected to the high supply voltage; and
a fourth thick oxide PMOS transistor with gate connected to the inverted input voltage, source connected to the second thick oxide PMOS transistor drain, and drain connected to the high supply voltage.

8. The level shifting circuit as claimed in claim 7, wherein:
the first NMOS transistor and second NMOS transistor are thin oxide NMOS transistors; and
the first thick oxide NMOS transistor and second thick oxide NMOS transistor are depletion NMOS transistors with threshold voltages no greater than zero.

9. The level shifting circuit as claimed in claim 7, further comprising:
a third NMOS transistor with gate connected to a first reference voltage, source connected to the first NMOS transistor drain, and drain connected to the first thick oxide NMOS transistor source; and
a fourth NMOS transistor with gate connected to the first reference voltage, source connected to the second NMOS transistor drain, and drain connected to the second thick oxide NMOS transistor source.

10. The level shifting circuit as claimed in claim 9, wherein the third NMOS transistor and fourth NMOS transistor are thin oxide NMOS transistors.

11. The level shifting circuit as claimed in claim 7, wherein the input voltage is subsequently between 0.5V to 2.5V.

12. The level shifting circuit as claimed in claim 7, wherein the output voltage is subsequently between 3V to 10V.
